(19) United States
(12) Patent Application Publication
(10) Pub. No.: US 2026/0252760 A1
(43) Pub. Date: Aug. 27, 2026

(54) SIMULATION DEVICE AND PROGRAM

(71) Applicant: FANUC CORPORATION, Minamitsuru-gun, Yamanashi (JP)

(72) Inventor: Norio TAKEI, Minamitsuru-gun, Yamanashi (JP)

(21) Appl. No.: 18/874,671

(22) PCT Filed: Jul. 19, 2022
(86) PCT No.: PCT/JP2022/028026

§ 371 Date: Dec. 13, 2024

(51) Int. Cl. G06F 30/20

(52) U.S. Cl. CPC G06F 30/20

(57) ABSTRACT

The objective of the present invention is to provide a simulation device and a program capable of simulating an operation of a robot, even without a branch determination being made by a human. A simulation device according to an embodiment is provided with a simulation unit which, for an operating program for operating a robot, the operating program including a branch for proceeding to different branch destinations depending on a state of a variable, simulates the operations of the robot when proceeding to each of the different plurality of branch destinations, by causing the state of the variable to vary such that the operating program proceeds to the different branch destinations.

### TECHNICAL FIELD

The present invention relates to a simulation device and a program.

### BACKGROUND ART

There is a technology called “offline simulation” in which the motion of a robot is simulated using a virtual robot on a computer. The offline simulation creates a virtual robot based on backup data on a real robot and the like to perform a simulation. The offline simulation is performed for the purpose of, for example, failure analysis or modification of a motion program.

### CITATION LIST

### Patent Document

Patent Document 1: Japanese Unexamined Patent Application, Publication No. 2014-144524

### DISCLOSURE OF THE INVENTION

### Problems to be Solved by the Invention

However, a real robot is connected to a programmable logic controller (PLC), a peripheral device, or the like via an input/output (I/O) connection. For this reason, the motion program for a robot includes input standbys and conditional branches for many I/Os. Accordingly, this prevents the motion of a robot from being easily simulated.

As a conventional technique, a method is known in which a signal status setting file is created and a simulation is performed while states of I/Os are changed based on settings (Patent Document 1) . In the conventional technique, a human needs to judge how the conditional branches generated by I/Os in the motion program should be created and set the conditional branches. Thus, a motion program with a complicated configuration requires many man-hours.

A problem to be solved by an embodiment of the present invention is to provide a simulation device and a program that enable a simulation of the motion of a robot without a human determining branches.

### Means for Solving the Problems

A simulation device according to an embodiment includes: a simulator configured to change states of a variable in a motion program which includes a plurality of programs for operating a robot and includes branches, at each of which a process of each program proceeds to different branch destinations depending on the states of the variable, such that the simulator executes a simulation of different motions of the robot when the process proceeds to the different branch destinations.

### Effects of the Invention

The present invention enables the simulation of the motions of a robot without a human determining branches.

### BRIEF DESCRIPTION OF THE DRAWINGS

FIG. 1 is a block diagram showing an exemplary configuration of a simulation system according to an embodiment and essential components included in the simulation system;

FIG. 2 is a flowchart showing exemplary processes to be performed by a processor in FIG. 1;

FIG. 3 is a flowchart showing exemplary processes to be performed by the processor in FIG. 1; and

FIG. 4 shows an exemplary result screen displayed on a display device in FIG. 1.

### PREFERRED MODE FOR CARRYING OUT THE INVENTION

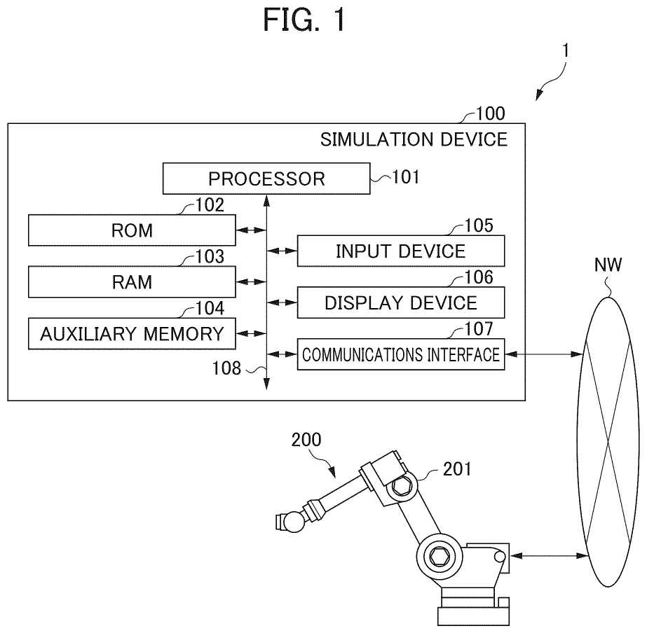

A simulation system according to an embodiment will be described below with reference to the drawings. Note that in each of the drawings for use to describe the following embodiment, the scale of each component may be appropriately changed. In addition, in each of the drawings for use to describe the following embodiment, some components may be omitted for the sake of explanation. In each of the drawings and the description, the same reference numerals denote similar elements. FIG. 1 is a block diagram showing an exemplary configuration of a simulation system 1 according to the embodiment and essential components included in the simulation system 1. The simulation system 1 includes a simulation device 100 and a robot 200, for example.

The simulation device 100 and the robot 200 are connected to a network NW, for example. The network NW is a communication network typically including a private network, such as an intranet .. The network NW is a communication network typically including a local area network (LAN). The network NW may be a communication network including the Internet. The network NW may be a communication network including a wide area network (WAN). The network NW may be a radio network of a wired network, or may be a combination of a radio network and a wired network. The network NW may be a communication network including a leased line or a public land mobile network.

The simulation device 100 performs an offline simulation for the robot 200. The simulation device 100 includes a processor 101, a read-only memory (ROM) 102, a random-access memory (RAM) 103, an auxiliary memory 104, an input device 105, a display device 106, and a communications interface 107 as examples. A bus 108 and the like connect these components together.

The processor 101 is a central part of a computer performing processes, such as operations and control, required to operate the simulation device 100, and performs various operations and processes. Examples of the processor 101 include a central processing unit (CPU), a micro processing unit (MPU), a system-on-a-chip (SoC), a digital signal processor (DSP), a graphics processing unit (GPO), an application specific integrated circuit (ASIC), a programmable logic device (PLD), a field-programmable gate array (FPGA), and the like. Alternatively, the processor 101 may be a combination of two or more of these examples. Still alternatively, the processor 101 may be a combination of one of these examples and a hardware accelerator or the like. The processor 101 controls the components of the simulation device 100 to implement various functions of the simulation device 100, based on programs, such as firmware, system software, and application software, stored in the ROM 102, the auxiliary memory 104, or the like. The processor 101 executes processes to be described later, based on the programs. Note that some of all of the programs may be installed in a circuit in the processor 101.

The ROM 102 and the RAM 103 are main memories of the computer that includes the processor 101 as a hub. The ROM 102 is a nonvolatile memory used exclusively for reading data out. The ROM 102 stores some of the programs, such as firmware. The ROM 102 also stores data and other types of information to be used by the processor 101 to perform various processes. The RAM 103 is a memory used for reading and writing data. The RAM 103 is used as a work area or the like where data to be temporarily used by the processor 101 to perform various processes are stored. The RAM 103 is typically a volatile memory.

The auxiliary memory 104 is an auxiliary memory of the computer that includes the processor 101 as a hub. Examples of the auxiliary memory 104 include an electric erasable programmable read-only memory (EEPROM), a hard disk drive (HDD), a flash memory, and the like. The auxiliary memory 104 stores one or more of the programs, such as system software and application software. The auxiliary memory 104 also stores data to be used by the processor 101 to perform various. processes, data created through the processes performed by the processor 101, various setting values, and the like.

In addition, the auxiliary memory 104 stores motion programs for the robot 200, for example.

The input device 105 accepts an operation performed by an operator of the simulation device 100 (hereinafter simply referred to as the “operator”). The input device 105 is, for example, a keyboard, a keypad, a touchpad, a mouse, of a controller. The input device 105 may be a voice input device.

The display device 106 displays a screen for informing the operator or the like of various types of information. The display device 106 is, for example, a display, such as a liquid crystal display or an organic electro-luminescence (EL) display. A touch panel may be used as a combination of the input device 105 and the display device 106. In other words, a display panel included in the touch panel may be used as the display device 106, and a pointing device operated by touch input in the touch panel may be used as the input device 105.

The communications interface 107 is an interface that allows the simulation device 100 to communicate via the network NW.

The bus 108, which includes a control bus, an address bus, a data bus, and the like, transmits signals exchanged by the components of the simulation device 100.

The robot 200 is, for example, a manipulator, a robot arm, or a robot and the like including these devices. The robot 200 is, for example, an articulated robot. The robot 200 includes one or more actuators 201 as an example.

Each actuator 201 is a component to drive with a motor or the like, such as a servomotor. Each actuator 201 rotates around a drive shaft to drive, for example.

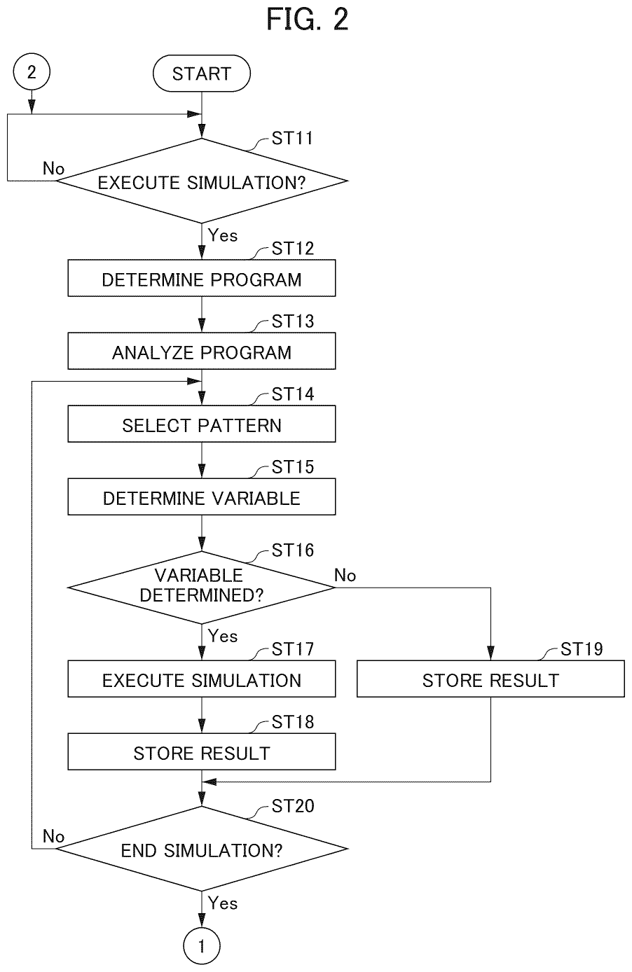

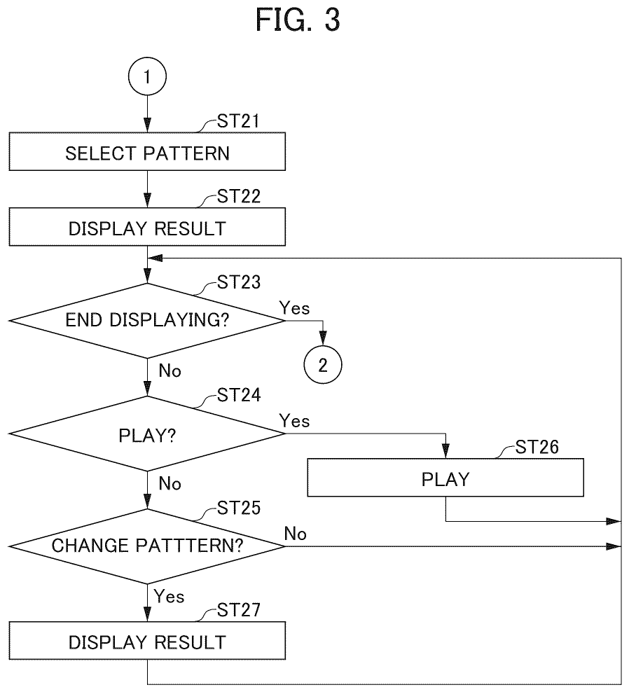

An operation of the simulation system 1 according to the embodiment will be described below with reference to FIGS. 2 and 3 and the like. The contents of processes in the following description of the operation are examples, and various processes that provide similar results may be appropriately used. FIGS. 2 and 3 are flowcharts each showing exemplary processes to be performed by the processor 101 of the simulation device 100. The processor 101 executes the processes shown in FIGS. 2 and 3, based on the programs stored in the ROM 102, the auxiliary memory 104, or the like.

In Step ST11 shown in FIG. 2, the processor 101 of the simulation device 100 determines whether or not a simulation of the motion programs for the robot 200 is executed. For example, if there is a simulation of a motion program which has not yet been executed, the processor 101 determines to execute the simulation of the motion program. For example, if there is a simulation of a motion program which has not yet been executed in a predetermined time, the processor 101 determines to execute the simulation of the motion program. For example, the processor 101 determines to execute the simulation of the motion program when there is an input instructing execution of the simulation of the motion program. The input of this instruction is based on, for example, an operation input given to the input device 105 by an operator. Alternatively, information indicative of the instruction may be input via the communications interface 107 from another device to the simulation device 100. If the processor 101 does not determine to execute the simulation of the motion program, the processor 101 determines “No” in Step ST11 and repeats the process in Step ST11. On the other hand, if the processor 101 determines to execute the simulation of the motion program, the processor 101 determines “Yes” in Step ST11 and advances the process to Step ST12.

In Step ST12, the processor 101 selects a motion program to be simulated. The processor 101 acquires the selected motion program from the auxiliary memory 104 or any other device. The motion program acquired last through the process in Step ST12 is hereinafter referred to as the “acquired program”.

For example, the processor 101 selects one of the motion programs that have not be simulated, and determines the selected motion program as the motion program to be simulated. For example, the processor 101 determines which of the motion programs should be simulated, based on an input indicating a target to be simulated. The input indicating the target is based on, for example, an operation input given to the input device 105 by an operator. Alternatively, information indicating the target may be input via the communications interface 107 from another device to the simulation device 100.

In Step ST13, the processor 101 analyzes the acquired program. The processor 101 checks how many execution patterns are included in the acquired program through the analysis of the acquired program. For example, if the processor 101 reads the acquired program and the acquired program includes branches, the count of the number of patterns is increased by (the number of the branches—1) per branch. The number of branches refers to a number of branching at one branch. Examples of the branch include an IF statement, a CASE statement and the like. If the branch is an IF statement, the number of branches is usually two. If the branch is a CASE statement, the number of branches is two or more. If the acquired program includes a loop that may be an infinite loop, the processor 101 does not count a branch destination included in this loop as one of the number of branches. The branch destination included in this loop refers to a branch target. that certainly executes this loop by the end of the acquired program.

The motion program including a function called “LOOP” described below is an exemplary motion program including a loop that may be an infinite loop. A number to the left of “:” in a code of a motion program described in the description and the drawing indicates on which line of a function the code is located. The fourth line of the function “LOOP” indicates a branch representative of an IF statement. The IF statement is split into one case where the condition “DI[1]=ON” is true and another case where the condition “DI[1]=ON” is false. The branch destination for the case where “DI[1]=ON” is true among these cases includes an instruction to jump to LABEL[1] on the second line. If the processor that executes the function “LOOP” jumps to the second line, the processor again executes the fourth line. In other words, if the condition “DI[1]=ON” is satisfied, the loop becomes an infinite loop.

Accordingly, regarding the IF statement on the fourth line, the branch destination is a branch destination included in the loop that may be an infinite loop for the case where the condition “DI[1]=ON” is true.

### Loop

1: POSITION[1]100%
2: LABEL[1]
3: POSITION[2]100%
4: IF (DI[1]=ON) THEN JUMP LABEL[1]
5: END

The processor 101 stores execution patterns of the acquired program in the RAM 103, the auxiliary memory 104, or the like in the form of, for example, a tree structure. In the tree structure, respective branches in the acquired program indicate internal nodes. The end of the acquired program indicates a leaf node. The internal node is a node to have child nodes. A leaf node is a node to have no child nodes.

The processor 101 creates a tree structure in such a way so as to exclude a branch destination that enters a loop that may be an infinite loop.

The processor 101 checks whether or not the acquired program is a motion program that does not contain a motion instruction, through the analysis of the acquired program. The motion instruction refers to an instruction to cause the actuator 201 of the robot 200 to move.

A motion program including a function called “RESET SIGNAL” indicated below is an exemplary motion program that does not contain a motion instruction. The motion program indicated below does not contain a motion instruction.

Accordingly, execution of the motion program indicated below will not cause the actuator 201 of the robot 200 to move.

### Reset Signal

1: DO[1]=OFF
2: DO[2]=OFF
3: DO[3]=OFF
4: DO[4]=OFF
5: DO[5]=OFF

In Step ST14, the processor 101 selects one of the execution patterns checked in Step ST13. For example, the processor 101 selects one leaf node from the tree structure to select an execution pattern. The selected execution pattern means that branches are traced from a root node to the selected leaf node without backtracking. For example, the processor 101 sets the nodes included in the selected execution pattern to a selected state, and thus indicates which of the execution patterns is being selected.

However, if one of the execution patterns is being selected, the processor 101 preferably selects one of the execution patterns close to the execution pattern being selected. A situation where one of the execution patterns is being selected means that the selection of the execution pattern in the process of previous Step ST14 has not been canceled. When selecting one of the execution patterns close to the execution pattern being selected, the processor 101 preferably changes the state of a node as deep as possible from the unselected state to the state of being selected to select one of the execution patterns.

The processor 101 executes, for example, the following processes (A1) to (A3) to select one of the execution patterns close to the execution pattern being selected. (A1) The processor 101 changes the state of the deepest one of the nodes in the state of being selected from the state of being selected to the state of having been selected. Then, the processor 101 advances to (A2).

(A2) If the deepest one of the nodes in the state of being selected has child nodes in the unselected state, the processor 101 changes the state of one of the child nodes in the unselected state to the state of being selected. Then, the processor 101 advances to (A3). If the deepest one of the nodes in the state of being selected does not have child nodes in the unselected state, the processor 101 returns to (A1). A situation where the node does not have child nodes in the unselected state includes a situation where the node does not have child nodes, i.e., a situation where the node is a leaf node.

(A3) If the last node in the state of being selected through (A2) or (A3) has child nodes, the processor 101 sets the child nodes to be in the state of being selected, and repeats (A3). On the other hand, if the last node set in the state of being selected through (A2) or (A3) does not have child nodes, the processor 101 completes the selection of the execution pattern.

In Step STIS, the processor 101 determines states of variables in order to execute a simulation of the motion of the robot 200 for the case where the acquired program is executed in the execution pattern being selected.

A method for determining the values of variables will be described with reference to a motion program including functions called “MAIN” and “SUBPROG” indicated below. The function “MAIN” is a function to be initially invoked during the execution of the motion program. The function “SUBPROG” is a function to be invoked by the function “MAIN”. The third to ninth lines of the function “SUBPROG” are replaced with “. . . ”, and are thus omitted. The third to ninth lines are supposed not to include branches.

### Main

1: POSITION[1]100%
2: POSITION[2]100%
3: IF (DI[1]=ON) THEN CALL SUBPROG
4: POSITION[1]100%
5: END

### Subprog

1: POSITION[1]100%
2: IF (DI[2]=ON) THEN JUMP LABEL[1]
10: END
11: LABEL[1]
12: POSITION[2]100%
13: END

This motion program includes two branches. These two branches are an IF statement on the third line of the function “MAIN” and an IF statement on the second line of the function “SUBPROG”.

The IF statement on the third line of the function “MAIN” is split into one case where the condition “DI[1]−ON” is true and another case where the condition “DI[1]=ON” is false, The IF statement on the second line of the function “SUBPROG” is split into one case where the condition “DI[2]=ON” is true and another case where the condition “DI[2]=ON” is false.

The function “SUBPROG” is invoked only if the IF statement on the third line of the function “MAIN” is true.

Accordingly, this motion program includes the following three execution patterns (B1) to (B3).
(B1) A case where the IF statement on the third line of the function “MAIN” is true.
(B2) A case where the IF statement on the third line of the function “MAIN” is false, and the IF statement on the second line of the function “SUBPROG” is true.
(B3) A case where the IF statement on the third line of the function “MAIN” is false, and the IF statement on the second line of the function “SUBPROG” is false.

To execute this motion program in the execution pattern (B1), the value of the variable DI[1] needs to be ON. If the value of the variable DI[1] is ON, the motion program is executed in the execution pattern (Bl) whatever the value of the variable DI[2] is.

To execute this motion program in the execution pattern (B2), it is necessary that the value of the variable DI[1] is not ON but the value of the variable DI[2] is ON. To execute this motion program in the execution pattern (B3), it is necessary that the value of the variable DI(1) is not ON and the value of the variable DI[2] is not ON.

The case where the value of a certain variable Vi is not a certain value X1 may include various other states than the state where the value is X1, such as the case where no value is entered into the variable V1 and the case where the variable V1 is null, in addition to the case where the value of the variable V1 is a value other than X1.

Specifically, if this motion program is simulated in the execution pattern (B2), the processor 101 sets the value of the variable DI[1] not to be ON, but sets the value of the variable DI[2] to be ON. Likewise, the processor 101 determines the states of the variables in accordance with the acquired program to be executed and the execution pattern.

For example, in the case of the motion program with a variable, the state of which changes in the process of the motion program, the processor 101 determines an initial state of the variable. For example, suppose that the motion program includes an IF statement and the value of the variable X2 is one, the IF statement is true. In addition, suppose that the motion program includes, before the IF statement, the statement “X2=X2+1” to increase the value of the variable X2 by one, but does not include another statement to change the value of the variable X2. In such a case, if the initial value of the variable X2 is zero, the IF statement is true. In this case, if the IF statement is desired to be true, the processor 101 sets the value of the variable X2 to be zero. If the IF statement is desired to be false, the processor 101 sets the value of the variable X2 to be a value except zero.

However, whatever the states of the variables are, there may be a case where it is not possible to execute the acquired program in the execution pattern being selected. For example, suppose that the IF statement on the second line of the function “SUBPROG” is rewritten as 2:IF (DI[1]=ON) THEN JUMP LABEL[1].

In this case, whatever the value of the variable DI[1] is, the motion program cannot be executed in the execution pattern (B2). This is because the IF statement on the second line of the function “SUBPROG” is certainly false if the IF statement on the third line of the function “MAIN” is false.

The processor 101 does not determine the states of the variables, for example, when the acquired program cannot be executed in the execution pattern being selected whatever the variables are.

In Step ST16, the processor 101 determines whether or not the states of the variables have been determined through the process in Step ST15. If the states of the variables have been determined, the processor 101 judges that the result is “Yes” in Step ST16, and advances the process to Step ST17.

In Step ST17, the processor 101 executes the acquired program with the variables set in the states determined in Step ST15, thereby executing the simulation of the motion of the robot 200. Accordingly, the processor 101 executes the simulation of the motion of the robot 200 for the case where the acquired program is executed in the execution pattern being selected.

The processor 101 calculates the motion of a virtual robot 200 in a virtual space to execute the simulation, The processor 101 calculates the motion of an actuator 201 of the virtual robot 200 based on the acquired program, for example, thereby calculating the motion of the virtual robot 200.

The processor 101 also calculates a trajectory of the robot 200 in the simulation. The processor 101 sets the track of an optional point of the robot 200, such as an arm tip of the robot 200, as the trajectory of the robot 200.

The processor 101 also calculates operating time and execution time that are required for the motion of the robot 200 in the simulation. The processor 101 calculates the operating time required for each of instructions included in the motion program. The execution time is the operating time from the start to the end of a motion produced by the motion program. In other words, the execution time is a sum of the operating time required for each instruction.

The processor 101 checks whether or not the acquired program is a motion program with short execution time in the simulation. For example, if the acquired program has execution time equal to or less than a predetermined threshold value TH1, the processor 101 determines that the acquired program is a motion program with short execution time. The length of the threshold value TH1 is determined in advance by an administrator or a designer of the simulation system 1, for example. For the case where a motion program includes a plurality of execution patterns, the processor 101 determines that the acquired program is a motion program with short execution time when the execution time of each of the execution patterns of the motion program is equal to or less than the threshold value TH1, for example.

The processor 101 may calculate the operating time not on an instruction-by-instruction basis but on a line-by-line basis. Alternatively, the processor 101 may calculate the operating time in other units. The operating time and the execution time are each an example of the time required for the motion of the robot.

In Step ST18, the processor 101 stores the result of the simulation in Step ST17 in the RAM 103, the auxiliary memory 104, or the like such that which of the execution patterns is used can be recognized. The simulation result includes the motion, trajectory, and operating time of the virtual robot 200.

On the other hand, if the processor 101 has not determined the states of the variables in Step ST15, the processor 101 judges the result to be “No” in Step ST16 and advances the process to Step ST19. Specifically, if the acquired program cannot be executed in the execution pattern being selected whatever the variables are, the processor 101 does not execute a simulation using the execution pattern being selected.

In Step ST19, the processor 101 stores what the execution pattern being selected cannot be executed in the RAM 103, the auxiliary memory 104, or the like.

After finishing the process in Step ST18 or ST19, the processor 101 advances to Step ST20. In Step ST20, the processor 101 determines whether or not the simulation is ended. If selection of all execution patterns has finished, for example, the processor 101 determines to finish the simulation. If none of the nodes are in an unselected state, the processor 101 assumes that the selection of all execution patterns has finished. If none of the leaf nodes are in an unselected state, the processor 101 assumes that the selection of all execution patterns has finished. If the processor 101 does not determine to end the simulation, the processor 101 determines “No” in Step ST20 and returns the process to Step ST14. On the other hand, if the processor 101 determines to end the simulation, the processor 101 determines “Yes” in Step ST20 and advances the process to Step ST21 in FIG. 3.

The processor 101 repeats the processes in Steps ST14 to ST20 as described above, such that the processor 101 executes the simulation of the acquired program in all execution Patterns except an unrealizable execution pattern.

As described above, the processor 101 performs the processes in Steps ST14 to ST20, such that the processor 101 functions as an example of the simulator. The simulator changes the states of the variables in the motion program, which includes a plurality of programs for operating the robot and includes branches, at each of which the process proceeds to different branch destinations depending on the states of the variables, such that the simulator executes a simulation of different motions of the robot when the process proceeds to the different branch destinations.

In Step ST21, the processor 101 selects one of the execution patterns of the acquired program. However, the processor 101 selects one of the execution patterns except unrealizable execution patterns. The execution pattern selected in the process in Step ST21 is hereinafter referred to as the “selected pattern”.

The processor 101 selects one of execution patterns on a random basis, for example. Alternatively, the processor 101 may select one of the execution patterns satisfying a condition under which a simulation result has been determined in advance. If two or more of the execution patterns satisfy the condition, the processor 101 selects randomly one of these execution patterns that satisfy the condition. Alternatively, for example, if two or more of the execution patterns satisfy the condition, the processor 101 may select the most suitable one among these execution patterns. If none of the execution patterns satisfy the condition, the processor 101 selects one of these execution patterns closest to the condition.

The condition determined in advance for selecting one of the execution patterns is set by, for example, a designer, an administrator, or an operator of the simulation device 1.

Conditions (C1) to (C9) will be indicated below as exemplary conditions. The condition may be a complex condition that is a combination of some of the conditions indicated below.
(C1) The execution time should be greater than or equal to a predetermined threshold value TH2.
(C2) The execution time should be equal to or less than a predetermined threshold value TH3.
(C3) The trajectory should pass through a predetermined location.
(C4) The trajectory should not pass through the predetermined location.
(C5) The length of the trajectory should be equal to or less than a predetermined threshold value TH4.
(C6) The length of the trajectory should be greater than or equal to a predetermined threshold value TH5.
(C7) The driven range of the actuator 201 during the motion of the virtual robot 200 in operation should fall within a predetermined range.
(C8) The position of the virtual robot 200 in operation should fall within a predetermined range,
(C9) The virtual robot 200 should perform a predetermined motion.

If two or more of the execution patterns satisfy the condition, and the trajectories of the motions in these execution patterns are similar to each other, the processor 101 may select any one of these execution patterns. If the distance between two trajectories is equal to or less than a predetermined value, the processor 101 assumes the two trajectories to be similar to each other. The processor 101 calculates a Euclidean distance between the locations at every unit time, and sets an average of the Euclidean distances to be the distance between the two trajectories. Alternatively, the processor 101 may set the distance between the two trajectories according to the Euclidean distances between the two trajectories which are integrated with respect to time from zero seconds to an execution time and divided by the execution time. It should be noted that the trajectories for use in time integration are time functions. Alternatively, if each of the Euclidean distances between the two trajectories is always equal to or less than a predetermined distance, the processor 101 may assume the two trajectories to be similar to each other.

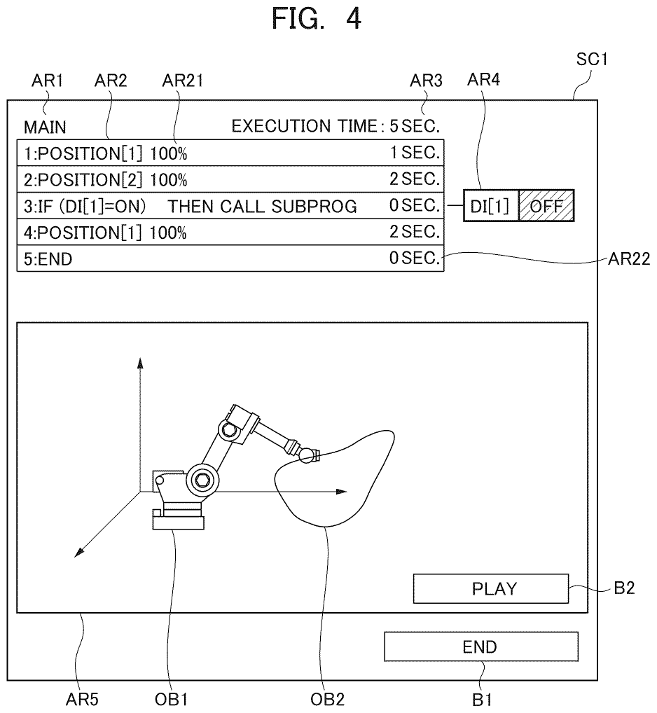

In Step ST22, the processor 101 generates an image corresponding to a result screen SCI as illustrated in FIG. 4. The processor 101 then directs the display device 106 to display the generated image. Upon receipt of the direction to display the generated image, the display device 106 displays the result screen SCI, FIG. 4 shows an exemplary result screen SC1 displayed on the display device 106. The result screen SC1 is a screen for displaying information on the selected pattern. Examples of the information include a result of simulation in the selected pattern. The result screen SC1 includes regions AR1 to ARS, an end button B1, and a play button B2, for example.

The region AR1 is a region where a function name, a program name indicative of an acquired program or the like are displayed.

The region AR2 is a region where the contents of the acquired program and the operating time for each instruction are displayed. The region AR2 includes regions AR21 and AR22.

The region AR21 is a region where the contents of the acquired program are displayed. The region AR21 displays an acquired program on an instruction-by-instruction basis or on a line-by-line basis, for example. It should be noted that the region AR21 displays only a portion of the acquired program to be executed in a selected pattern. Alternatively, the region AR21 may display the entirety of the acquired program.

The region AR22 is a region where operating time for the acquired program is displayed. The region AR22 displays the operating time on an instruction-by-instruction basis or on a line-by-line basis, for example.

The region ARS is a region where the execution time of the acquired program is displayed.

The region AR4 is a region where it is displayed which branch destination the selected pattern proceeds to at the branch included in the acquired program which is displayed on the region AR21. The region AR4 is a button to be operated by an operator to direct the simulation device 100 to display the result obtained if the process proceeds from the branch to another branch. In other words, the region ARA is a button to be operated by the operator to direct the simulation device 100 to change the selected pattern. The number of regions AR4 included in the result screen SC1 is the number of branches. In FIG. 4, the number of regions AR4 is one.

The region ARS is a region for displaying the result of simulation in the selected pattern. The region ARS displays a virtual robot OB1 and a trajectory OB2 in a virtual space, for example. The virtual robot OB1 is the virtual robot 200. The virtual robot OB1 is an image, a three-dimensional (3D) object, or the like.

The trajectory OB2 is an image, a 3D object, or the like showing a simulation of a trajectory in a selected pattern. The processor 101 generates the trajectory OB2 based on the result of the simulation in the selected pattern.

The end button B1 is a button to be operated by an operator to direct the simulation device 100 to end the display of the result screen SC1.

The play button B2 is a button to be operated by an operator to direct the simulation device 100 to play a video or any other image showing the simulation result (hereinafter referred to as the “simulation video”).

In Step ST23, the processor 101 determines whether or not an operation has been performed to end the display of the result screen SCI. In other words, the processor 101 determines whether or not an operation determined in advance, such as the operation of the end button B1, has been performed. IF an operation is not performed to end the display of the result screen SC1, the processor 101 determines “NO” in Step ST23 and advances the process to Step ST24.

In Step ST24, the processor 101 determines whether or not an operation has been performed to play the simulation video.

In other words, the processor 101 determines whether or not an operation determined in advance, such as the operation of the play button B2, has been performed. If an operation is not performed to play the simulation video, the processor 101 determines “No” in Step ST24 and advances the process to Step ST25.

In Step ST25, the processor 101 determines whether or not an operation has been performed to change the selected pattern. In other words, the processor 101 determines whether or not an operation determined in advance, such as the operation of the region AR4, has been performed. If an operation is not performed to change the selected pattern, the processor 101 determines “No” in Step ST25 and returns the process to Step ST23. In this manner, the processor 101 enters into a standby state where Steps ST23 to ST25 are repeated until an operation is performed to give a direction to end the display of the result screen SC1, to play the simulation video, or to change the selected pattern.

As described above, the processor 101 performs the process in Step ST25 in collaboration with the input device 105 to function as an example of the input unit that receives an input to instruct the states of the variables.

If an operation is performed to end the display of the result screen SC1 while the processor 101 is in a standby state in Steps ST23 to ST25, the processor 101 determines “Yes” in Step ST23 and advances the process to Step ST11.

If an operation is performed to play the simulation video while the processor 101 is in the standby state in Steps ST23 to ST25, the processor 101 determines “Yes” in Step ST24 and advances the process to Step ST26.

In Step ST26, the processor 101 plays the simulation video showing the result of simulation in the selected pattern in the region ARS. The simulation video may be a two-dimensional (2D) video or a 3D video. If the simulation video is a 3D video, the perspective may be changeable. The simulation video is a video showing that the virtual robot OBI performs a motion in accordance with the result of simulation.

The processor 101 may generate a simulation video in advance before the operation of the play button B2, or may generate a simulation video after the operation of the play button B2.

If an operation is performed to give a direction to change the selected pattern while the processor 101 is in a standby state for Steps ST23 to ST25, the processor 101 determines “Yes” in Step ST25 and advances the process to Step ST27.

In Step ST27, the processor 101 changes the selected pattern to that instructed through the operation of the region AR4. The processor 101 then displays the result screen SC1 corresponding to a newly selected pattern like the process in Step ST23. After the process in Step ST27, the processor 101 returns the process to Step ST23.

As described above, the processor 101 performs the process in Step ST27 in collaboration with the display device 106 to function as an example of the display that displays the result of the simulation using the states of the variables according to the input entered into the input unit.

According to the simulation system 1 of the embodiment, the simulation device 100 automatically executes a simulation of a motion program in a plurality of execution patterns. Accordingly, it is possible for the simulation device 100 of the embodiment to simulate the motion of a robot without a human determining branches. This results in the reduction of manpower and man-hours.

According to the simulation system 1 of the embodiment, the simulation device 100 calculates the trajectory of the motion of the robot 200 in each of the execution patterns. This allows the operator or the like to check the trajectory in each execution pattern.

According to the simulation system 1 of embodiment, the simulation device 100 calculates the operating time and execution time for each of the execution patterns. This allows the operator of the like to check the operating time and execution time in each execution pattern.

According to the simulation system 1 of the embodiment, the simulation device 100 displays the result of simulation in the execution pattern corresponding to the input performed by the operator on the display device 106. This allows the operator to check the result of simulation in a desired execution pattern.

According to the simulation system 1 of the embodiment, the simulation device 100 displays a video showing the result of simulation. Accordingly, it is possible for the simulation device 100 to simply inform an operator or the like of the result of simulation.

According to the simulation system 1 of the embodiment, the simulation device 100 automatically selects one of the execution patterns based on a condition determined in advance. Accordingly, it is possible for the simulation device 100 to display the result of simulation in the execution pattern which meets the condition determined in advance.

The foregoing embodiment may be modified as follows. The processor 101 may allow the tree structure to include a branch destination to enter the loop that may be an infinite loop. In this case, the processor 101 does not select such a branch destination in Step ST14, for example.

The processor 101 does not need to count a branch destination included in an instruction to return to a previous step even if the loop is not likely to be an infinite loop. This eliminates the need for analyzing whether or not the instruction to return to the previous step may be an infinite loop, The branch destination included in the instruction to return to the previous step refers to a branch destination that certainly executes this instruction by the end of the motion program.

The processor 101 may also perform a simulation in the execution pattern including the branch destination to enter the loop that may be an infinite loop. In this case, the processor 101 executes the simulation until the number of times executed for the loop becomes greater than or equal to a predetermined number of times.

In Step ST12, the processor 101 may determine a plurality of motion programs as motion programs to be simulated, In this case, all of the motion programs are acquired programs. If the number of acquired programs is two or more, the processor 101 executes the processes in Steps ST14 to ST20 for each of the acquired programs.

If the number of acquired programs is two or more, the processor 101 selects one of the acquired programs in Step ST21. The processor 101 then selects one of the execution patterns for the selected acquired program. The processor 101 selects one of the acquired programs on a random basis, for example. Alternatively, the processor 101 may select one of the acquired programs satisfying a condition determined in advance. If two or more of the acquired programs satisfy the condition, the processor 101 selects one of these acquired programs satisfying the condition on a random basis.

Alternatively, for example, if two or more of the acquired programs satisfy the condition, the processor 101 may select the most suitable one of these acquired programs. If none of the acquired programs satisfy the condition, the processor 101 may select one of these acquired programs closest to the condition.

The condition determined in advance for selecting an acquired program is set by a designer, an administrator, an operator or the like of the simulation device 1, for example.

Conditions (D1) to (D3) are shown below as exemplary conditions. The condition may be a complex condition that is a combination of some of the conditions described below.
(D1) The acquired program is not a motion program without a motion instruction.
(D2) The acquired program is not a motion program with a short execution time.
(D3) The acquired program is a motion program with a short execution time.

As described above, the processor 101 performs the process in Step ST21 to function as an example of the selector that automatically selects at least either one selected from the plurality of programs or the states of the variables, based on the condition determined in advance.

According to the simulation system 1 of the embodiment, the simulation device 100 automatically selects the acquired program based on the condition determined in advance. Accordingly, it is possible for the simulation device 100 to display the result of simulation of the acquired program meeting the predetermined condition.

The processor 101 may create a tree structure to exclude a motion pattern that is not executable in program analysis.

The processor 101 may change the states of the variables midway in the process of the program and simulate the unrealizable execution pattern.

The processor 101 may automatically play the simulation video along with the display of the result screen SCI.

The processor 101 may be replaced with a circuit of hardware configuration with respect to its parts or entirety of the process to be implemented by the program in the embodiment.

The program implementing the process in the embodiment is transferred while being stored in a non-transitory recording medium inside a device, for example. However, the device may be transferred without storing the program. The program may be separately transferred and then written in the device. In this case, the program can be transferred by being recorded in, for example, a removable and non-transitory storage medium or by being downloaded via a network, such as the Internet or a local area network (LAN).

While the embodiment of the present invention has been described above, the embodiment is merely an example, and does not limit the scope of the present invention. The embodiment of the present invention can be implemented in various modes without departing from the sprit of the present invention.

### EXPLANATION OF REFERENCE NUMERALS

1 Simulation System
100 Simulation Device
101 Processor
102 ROM
103 RAM
104 Auxiliary Memory
105 Input Device
106 Display Device
107 Communications Interface
108 Bus
200 Robot
201 Actuator
OB1 Virtual Robot
OB2 Trajectory

1. A simulation device comprising:
a simulator configured to change states of a variable in a motion program which includes a plurality of programs for operating a robot and includes branches, at each of which a process of each program proceeds to different branch destinations depending on the states of the variable, such that the simulator executes a simulation of different motions of the robot when the process proceeds to the different branch destinations.

2. The simulation device according to claim 1, wherein
the simulator calculates trajectories of the motions of the robot in the simulation.

3. The simulation device according to claim 1, wherein
the simulator calculates a time required for each motion of the robot.

4. The simulation device according to claim 1 further comprising:
an input unit configured to receive an input to indicate the states of the variable; and
a display configured to display a result of the simulation using the states of the variable according to the input entered into the input unit.

5. The simulation device according to claim 1 further comprising:
a display configured to display a video showing a result of the simulation.

6. The simulation device according to claim 1, further including:
a selector configured to automatically select at least either a program selected from the plurality of programs or the states of the variable based on a predetermined condition.

7. A non-transitory machine-readable storage medium storing a program which causes a processor of a simulation device to function as a simulator configured to perform an operation comprising:
changing states of a variable in a motion program which includes a plurality of programs for operating a robot and branches, at each of which a process of each program proceeds to different branch destinations depending on the states of the variable, such that the simulator executes a simulation of different motions of the robot when the process proceeds to the different branch destinations.
